(19) United States
(12) Patent Application Publication
(10) Pub. No.: US 2023/0326809 A1
(43) Pub. Date: Oct. 12, 2023

(54) STANDARD WAFERS, METHOD OF MAKING THE SAME AND CALIBRATION METHOD

(71) Applicant: Zing Semiconductor Corporation, Shanghai (CN)

(72) Inventors: Gongbai CAO, Shanghai (CN); Shuai PAN, Shanghai (CN)

(73) Assignee: Zing Semiconductor Corporation, Shanghai (CN)

(21) Appl. No.: 18/066,145

(22) Filed: Dec. 14, 2022

(30) Foreign Application Priority Data
Apr. 8, 2022 (CN) 202210368791.8

(51) Int. Cl. H01L 21/66; H01L 21/02

(52) U.S. Cl. CPC H01L 22/14; H01L 21/02293

(57) ABSTRACT

The present invention provides standard wafers, a method of making the same and a calibration method. The method of making a standard wafer comprise providing a silicon substrate having a first conductive type; forming a reverse epitaxy layer having a second conductive type; forming a target epitaxy layer having the first conductive type; measuring a measurement of a resistivity of the target epitaxy layer with four point probing, the measurement being utilized as a standard resistivity of the standard wafer. In the present invention, the method of making a standard wafer is low-cost and convenient because the standard wafer is made with electrical isolation formed with the reverse epitaxy layer positioned between the silicon substrate and the target epitaxy layer formed after forming the reverse epitaxy layer facilitates in presenting a resistivity of the target epitaxy layer greater than 50 ohm/cm at first and then utilizing the four point probing to measure the resistivity of the target epitaxy layer as the resistivity of the standard wafer.

### FIELD OF THE INVENTION

The present invention generally relates to a semiconductor technical field, and specifically, relates to a method of making a standard wafer for resistivity measurement, a standard wafer and a calibration method.

### BACKGROUND OF THE INVENTION

Measuring methods of a resistivity of polymorphous silicon Epi wafer (an epitaxy layer) mainly comprise four point probing (4PP), mercury probe capacitance-voltage measurement (Hg probe), spreading resistance profile (SRP), air-gap capacitance voltage (ACV) and QC surface charge profiler (QCS). QCS has an advantage over all of the methods because it is non-contact measurement which prevents from pollution of the Epi wafer, facilitates reuse, and has relatively greater measuring range to adapt to measurement of a resistivity of a high impedance Epi wafer.

Before measuring QCS for an Epi wafer, a standard wafer may be utilized for calibrating the QCS apparatus. Resistivity of the standard wafer may be close to the resistivity of the Epi wafer as far as possible to raise precision of the measurement of the resistivity. Current standard wafers are usually made from a single crystal which is usually a top end or a trailing end of an ingot. However, because a resistivity of the top end or the trailing end of the ingot is usually too low and limited to provide a standard wafer having a high or relatively high resistivity (such as greater than 50 ohm/cm). If the standard wafer is made with customizing the single crystal correspondingly, the cost will be too high.

### SUMMARY OF THE INVENTION

One aspect of the present invention is to a method of making a standard wafer for resistivity measurement, a standard wafer and a calibration method providing the standard wafer with low-cost and convenience.

In one aspect of the invention, an embodiment of the invention is provided that a method of making a standard wafer for resistivity measurement, the standard wafer being utilized for calibration before measuring a resistivity of an Epi wafer having a first conductive type, comprising steps of: providing a silicon substrate having the first conductive type; forming a reverse epitaxy layer overlying the silicon substrate, the reverse epitaxy layer having a second conductive type which is opposite to the first conductive type, and a resistivity of the reverse epitaxy layer being less than or equal to 10 ohm/cm; forming a target epitaxy layer overlying the reverse epitaxy layer, the target epitaxy layer having the first conductive type, and a resistivity of the target epitaxy layer being greater than 50 ohm/cm and a thickness of the target epitaxy layer being greater than 35 μm; and measuring a measurement of the resistivity of the target epitaxy layer with four point probing (4PP), the measurement being utilized as a standard resistivity of the standard wafer, and the first conductive type of the target epitaxy layer being utilized as a conductive type of the standard wafer.

Optionally, the step of measuring a measurement of the resistivity of the target epitaxy layer with QC surface charge profiler.

Optionally, a step of cleaning the silicon substrate may be performed before forming the reverse epitaxy layer.

Optionally, the resistivity of the reverse epitaxy layer may be within 0.1-10 ohm/cm.

Optionally, a thickness of the reverse epitaxy layer may be within 5-10 μm.

Optionally, the resistivity of the target epitaxy layer may be within 50-500 ohm/cm.

Optionally, the thickness of the target epitaxy layer may be within 35-50 μm.

In another aspect of the invention, an embodiment of the invention is provided that a method of making a standard wafer for resistivity measurement, the standard wafer being utilized for calibration before measuring a resistivity of an Epi wafer having a first conductive type, comprising steps of: providing a silicon substrate having a second conductive type which is opposite to the first conductive type; forming a target epitaxy layer overlying the silicon substrate, the target epitaxy layer having the first conductive type, a resistivity of the target epitaxy layer being greater than 50 ohm/cm, and a thickness of the target epitaxy layer being greater than 35 μm; and measuring a measurement of the resistivity of the target epitaxy layer with four point probing, the measurement being utilized as a standard resistivity of the standard wafer, and the first conductive type of the target epitaxy layer being utilized as a conductive type of the standard wafer.

In another aspect of the invention, an embodiment of the invention is provided that a standard wafer for resistivity measurement, wherein the standard wafer is made with one of the methods of making a standard wafer as mentioned above.

In another aspect of the invention, an embodiment of the invention is provided that a calibration method, performing calibration before measuring a resistivity of an Epi wafer with a standard wafer or resistivity measurement as mentioned above, comprising steps of: obtaining a conductive type and a predicted range of resistivity of an Epi wafer; choosing at least two of the standard wafers, the conductive type of which is the same as the conductive type of the Epi wafer, and a range of a standard resistivity of the standard wafer overlapping the predicted range of resistivity; and utilizing the standard wafer to perform a calibration before measuring the resistivity of the Epi wafer.

The present invention provides a solution of forming a reverse epitaxy layer and a target epitaxy layer sequentially on a silicon substrate, forming an electrical isolation with the reverse epitaxy layer between the silicon substrate and the target epitaxy layer, or forming the target epitaxy layer on the silicon substrate directly, and then providing a resistivity of the target epitaxy layer which is greater than 50 ohm/cm. A measurement of the resistivity of the target epitaxy layer may be obtained with four point probing to be utilized as a standard resistivity of the standard wafer, so as to provide the standard wafer having a higher resistivity and made with a low-cost and convenient method.

### BRIEF DESCRIPTION OF THE DRAWINGS

Various objects and advantages of the present invention will be more readily understood from the following detailed description when read in conjunction with the appended drawing, in which:

FIG. 1 shows a flow chart of a method of making a standard wafer for resistivity measurement according to an embodiment of the present invention;

FIGS. 2A-2C show structural perspective views corresponding to steps of a method of making a standard wafer for resistivity measurement according to an embodiment of the present invention.

### DESCRIPTION OF EMBODIMENTS OF THE INVENTION

Reference is now made to the following examples taken in conjunction with the accompanying drawings to illustrate implementation of the present invention. Please also note that the figures provided here are only exemplary. Only elements relative to the invention are shown therein. Actual number, shape, sizes, type and proportion may be varied in an implementation. Layout or arrangement may be more complicated.

The present disclosure illustrates various aspects of the embodiments according to the present invention, which may be implemented in various ways. Please note that structures and/or functionalities described here is only for description and those skilled in the art should understand that any one of the aspects may be implemented solely or in a combination. For instance, the device and/or method may be implemented in any number or field. Further, other structure and/or functionality may be used to implement the device and/or method.

The terminology used here is for the purpose of describing particular embodiments only and is not intended to limit the present application. Singular forms of “a,” “an,” and “the” may be intended to include the plural forms as well, unless the context clearly indicates otherwise. The terms “or” usually comprise “and/or.” The terms “a few” usually comprise “at least one.” The terms “at least two” usually comprise “two or more than two.” It is also to be understood that “first,” “second” and “third” are only exemplary but not intended to imply relative importance or indicate actual quantity of a feature. Therefore, the feature limited by “first,” “second” and “third” may include one or at least two of the feature, unless explicit description is specified.

### Embodiment 1

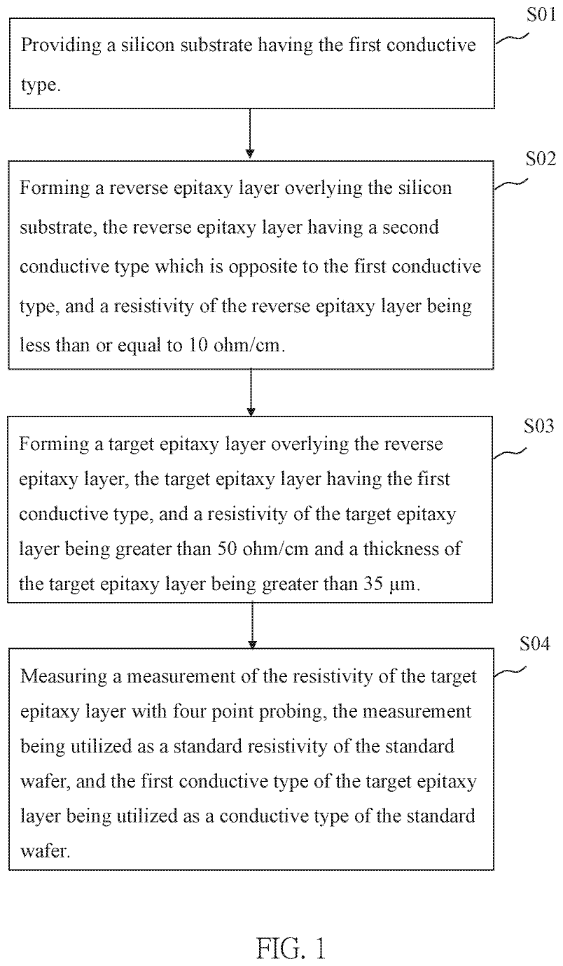

FIG. 1 shows a flow chart of a method of making a standard wafer for resistivity measurement according to an embodiment of the present invention.

As shown in FIG. 1, a method of making a standard wafer for resistivity measurement, the standard wafer being utilized for calibration before measuring a resistivity of an Epi wafer having a first conductive type, may comprise steps of: step S01: providing a silicon substrate having the first conductive type; step S02: forming a reverse epitaxy layer overlying the silicon substrate, the reverse epitaxy layer having a second conductive type which is opposite to the first conductive type, and a resistivity of the reverse epitaxy layer being less than or equal to 10 ohm/cm; step S03: forming a target epitaxy layer overlying the reverse epitaxy layer, the target epitaxy layer having the first conductive type, and a resistivity of the target epitaxy layer being greater than 50 ohm/cm and a thickness of the target epitaxy layer being greater than 35 μm; and step S04: measuring a measurement of the resistivity of the target epitaxy layer with four point probing (4PP), the measurement being utilized as a standard resistivity of the standard wafer, and the first conductive type of the target epitaxy layer being utilized as a conductive type of the standard wafer.

The Epi wafer may be an epitaxial silicon wafer or a substrate for resistivity measurement, a surface of which is covered by an epitaxy layer a thickness of which is thicker (usually greater than 1 μm). Here, a method of measuring a resistivity, such as QC surface charge profiler (QCS) may be applied. Before a measurement of the resistivity is performed, a standard wafer may be utilized for a calibration of a QCS apparatus to ensure precision of the measurement.

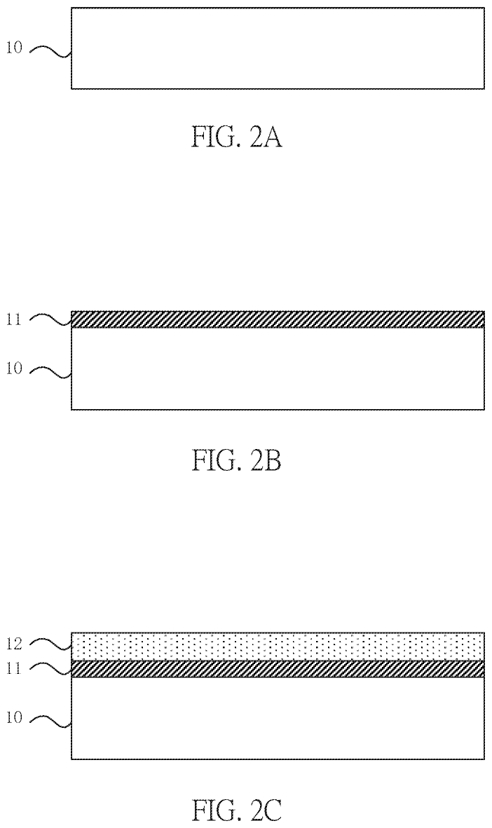

FIGS. 2A˜2C show structural perspective views corresponding to steps of a method of making a standard wafer for resistivity measurement according to an embodiment of the present invention. Referring to FIGS. 2A˜2C as well, method of making a standard wafer for resistivity measurement may be further detailed.

At first, as shown in FIG. 2A, a step S01 may be performed to provide a silicon substrate 10, the silicon substrate 10 has a first conductive type.

The silicon substrate 10 may be of a single crystal with any appropriate crystal direction, size, thickness and resistivity, and preferably, a thickness and sizes of the silicon substrate 10 may be the same as those of the Epi wafer to be measured to reduce calibration and adjustment before or during the measurement and facilitate simplifying movement and raising precision.

In the present embodiment, a 300-mm-diameter silicon substrate is taken as an example of the silicon substrate 10. The silicon substrate 10 has the same conductive type as that of the Epi wafer to be measured, i.e. the first conductive type. The first conductive type may be N type or P type.

Then, referring to FIG. 2B, a step S02 may be performed to form a reverse epitaxy layer 11, the reverse epitaxy layer 11 overlies the silicon substrate 10, the reverse epitaxy layer 11 has a second conductive type, the second conductive type is opposite to the first conductive type, and a resistivity of the reverse epitaxy layer 11 is less than or equal to 10 ohm/cm.

For example, a vapor phase epitaxy process may be applied to the silicon substrate 10 to form the reverse epitaxy layer 11. The reverse epitaxy layer 11 has a conductive type which is opposite to that of the silicon substrate 10 (or Epi wafer) to form an electrical isolation between the reverse epitaxy layer 11 and the silicon substrate 10. Specifically, with the vapor phase epitaxy process, a gas which may comprise SiHCl₃ and H₂ may be utilized, a N type dopant which may comprise PCl₃, PH₃ or AsCl₃ may be utilized, a P type dopant which may comprise BCl₃, BBr₃ or B₂H₆ may be utilized, a reacting temperature such as 800° C.-1300° C. may be set. Please note that aforesaid material and setting are only exemplary, the form reverse epitaxy layer 11 may be formed with other suitable epitaxy process.

Preferably, the reverse epitaxy layer 11 may have a relatively low resistivity (i.e. a relatively high doping content) to form a better electrical isolation with a thinner reverse epitaxy layer 11 and the silicon substrate 10, so as to raise yield and reduce cost of production. In the present embodiment, the resistivity of the reverse epitaxy layer 11 may be 0.1 ohm/cm˜10 ohm/cm, the thickness of the reverse epitaxy layer 11 may be 5 μm˜10 μm, wherein the resistivity of the reverse epitaxy layer 11 may be less than the resistivity of the silicon substrate 10, and the closer of the two resistivities are, the thicker the reverse epitaxy layer 11 is. Of course, the thickness of the reverse epitaxy layer 11 may be greater than 10 μm.

Before performing the epitaxy process, a step of cleaning the silicon substrate 10 may be performed to remove impurities and an oxide layer on the silicon substrate 10.

Then, referring to FIG. 2C, a step S03 may be performed to form a target epitaxy layer 12. The target epitaxy layer 12 may overly the reverse epitaxy layer 11, the target epitaxy layer 12 may have the first conductive type, a resistivity of the target epitaxy layer 12 may be greater than 50 ohm/cm and a thickness of the target epitaxy layer 12 may be greater than 35 μm.

The target epitaxy layer 12 formed with the epitaxy process has the same conductive type as that of the Epi wafer, which is opposite to the conductive type of the reverse epitaxy layer 11, i.e. the first conductive type. The epitaxy process forming the target epitaxy layer 12 may be a vapor phase epitaxy process for example, and may refer to the process forming the reverse epitaxy layer 11.

The resistivity of the target epitaxy layer 12 may refer to a range of the resistivity of the Epi wafer to be measured, and may be set as any proper value within a measuring range of the QCS apparatus, such as 0-500 ohm/cm. Therefore, a common low-resistivity single-crystal silicon wafer may be utilized as the standard wafer for an Epi wafer the resistivity of which is lower than 50 ohm/cm, but in the present embodiment, the standard wafer formed here is especially utilized for a high-resistivity high-impedance Epi wafer, i.e. the resistivity of the target epitaxy layer 12 may be 50 ohm/cm˜500 ohm/cm. During actual resistivity measurement, the standard wafer may be chosen depending on a predicted range of resistivity of the Epi wafer to be measured. Preferably, a standard wafer may be made to meet the predicted range of resistivity of the Epi wafer to be measured to raise precision.

In the present embodiment, the thickness of the target epitaxy layer 12 may be greater than 35 μm, and due to the thicker target epitaxy layer 12, precision and stability of the measurement of the resistivity the target epitaxy layer 12 may be improved, and meanwhile, better electrical isolation may be formed between the target epitaxy layer 12 and the reverse epitaxy layer 11. Preferably, the thickness of the target epitaxy layer 12 may be 35 μm˜50 μm to increase formation speed to adapt to the QCS apparatus.

Then, a step S04 may be performed to measure a measurement of the resistivity of the target epitaxy layer 12 with 4PP, the measurement may be utilized as a standard resistivity of the standard wafer, and the conductive type of the target epitaxy layer 12 may be utilized as the conductive type of the standard wafer.

Because the reverse epitaxy layer 11 may electrically isolate the silicon substrate 10 and the target epitaxy layer 12, the measurement of resistivity measured with 4PP is actually the resistivity of the target epitaxy layer 12, the resistivity of the target epitaxy layer 12 may be taken as the standard resistivity of the standard wafer, and the conductive type of the target epitaxy layer 12 may be taken as the conductive type of the standard wafer. When obtaining the measurement of the resistivity of the target epitaxy layer 12 with 4PP, multipoint measurement may be utilized to calculate an average of measurement to increase precision.

### Embodiment 2

The present invention provides another method of making a standard wafer for resistivity measurement.

According to the method of making a standard wafer for resistivity measurement of the present embodiment, the standard wafer being utilized for calibration before measuring a resistivity of an Epi wafer having a first conductive type, the method may comprise steps of: providing a silicon substrate having a second conductive type which is opposite to the first conductive type; forming a target epitaxy layer overlying the silicon substrate, the target epitaxy layer having the first conductive type, a resistivity of the target epitaxy layer being greater than 50 ohm/cm, and a thickness of the target epitaxy layer being greater than 35 μm; and measuring a measurement of the resistivity of the target epitaxy layer with four point probing, the measurement being utilized as a standard resistivity of the standard wafer, and the first conductive type of the target epitaxy layer being utilized as a conductive type of the standard wafer.

Specifically, because the silicon substrate has the second conductive type and both the Epi wafer to be measured and the target epitaxy layer have the first conductive type, in the present embodiment, a step of forming the reverse epitaxy layer, as mentioned in the first embodiment, may be omitted, so as to form the target epitaxy layer overlying the silicon substrate on a surface of the silicon substrate. Please refer to the details of the silicon substrate and the target epitaxy layer illustrated in the first embodiment which will be not repeated here.

When making the standard wafer, the steps may be simplified depending on the conductive type of the layer of epitaxy (the Epi wafer to be measured) and the conductive type of the silicon substrate.

### Embodiment 3

The present embodiment provides a standard wafer for resistivity measurement, the standard wafer may be made with the method of making a standard wafer for resistivity measurement as illustrated in the first or second embodiment. The standard wafer may be utilized to calibrate a QCS apparatus before resistivity measurement of an Epi wafer.

### Embodiment 4

The present embodiment provides a calibration method, performing calibration before measuring a resistivity of an Epi wafer with a standard wafer or resistivity measurement as mentioned above. The calibration method may comprise steps of: obtaining a conductive type and a predicted range of resistivity of an Epi wafer; choosing at least two of the standard wafers, the conductive type of which is the same as the conductive type of the Epi wafer, and a range of a standard resistivity of the standard wafer overlapping the predicted range of resistivity; and utilizing the standard wafer to perform a calibration before measuring the resistivity of the Epi wafer.

A standard wafer a standard resistivity of which falls within a measuring range may be utilized for calibration of a QCS apparatus, and afterwards, a resistivity of several Epi wafers may be measured to ensure a predicted range of resistivity of the epitaxy layer.

According to the predicted range of resistivity and the conductive type of the Epi wafer, several standard wafers having the same conductive type but different standard resistivity may be chosen, wherein the smallest standard resistivity may be less than or equal to a minimum of the predicted range of resistivity and the largest standard resistivity may be larger than or equal to a maximum of the predicted range of resistivity. Of course, one or two more standard wafers fall between the minimum and the maximum of the predicted range of resistivity evenly may be utilized to improve the precision.

The calibration of the QCS apparatus may be performed with the standard wafer(s) according to a common operation details of which are not needed here.

To sum up, the present invention provides a solution of forming a reverse epitaxy layer and a target epitaxy layer sequentially on a silicon substrate, forming an electrical isolation with the reverse epitaxy layer between the silicon substrate and the target epitaxy layer, or forming the target epitaxy layer on the silicon substrate directly, and then providing a resistivity of the target epitaxy layer which is greater than 50 ohm/cm. A measurement of the resistivity of the target epitaxy layer may be obtained with four point probing to be utilized as a standard resistivity of the standard wafer, so as to provide the standard wafer having a higher resistivity and made with a low-cost and convenient method.

It is to be understood that these embodiments are not meant as limitations of the invention but merely exemplary descriptions of the invention with regard to certain specific embodiments. Indeed, different adaptations may be apparent to those skilled in the art without departing from the scope of the annexed claims. For instance, it is possible to add bus buffers on a specific data bus if it is necessary. Moreover, it is still possible to have a plurality of bus buffers cascaded in series.

What is claimed is:

1. A method of making a standard wafer for resistivity measurement, the standard wafer being utilized for calibration before measuring a resistivity of an Epi wafer having a first conductive type, comprising steps of:
providing a silicon substrate having the first conductive type;
forming a reverse epitaxy layer overlying the silicon substrate, the reverse epitaxy layer having a second conductive type which is opposite to the first conductive type, and a resistivity of the reverse epitaxy layer being less than or equal to 10 ohm/cm;
forming a target epitaxy layer overlying the reverse epitaxy layer, the target epitaxy layer having the first conductive type, and a resistivity of the target epitaxy layer being greater than 50 ohm/cm and a thickness of the target epitaxy layer being greater than 35 μm; and
measuring a measurement of the resistivity of the target epitaxy layer with four point probing, the measurement being utilized as a standard resistivity of the standard wafer, and the first conductive type of the target epitaxy layer being utilized as a conductive type of the standard wafer.

2. The method of making a standard wafer according to claim 1, wherein the step of measuring a measurement of the resistivity of the target epitaxy layer with QC surface charge profiler.

3. The method of making a standard wafer according to claim 1, further comprising:
cleaning the silicon substrate before forming the reverse epitaxy layer.

4. The method of making a standard wafer according to claim 1, wherein the resistivity of the reverse epitaxy layer is within 0.1-10 ohm/cm.

5. The method of making a standard wafer according to claim 4, wherein a thickness of the reverse epitaxy layer is within 5-10 μm.

6. The method of making a standard wafer according to claim 1, wherein the resistivity of the target epitaxy layer is within 50-500 ohm/cm.

7. The method of making a standard wafer according to claim 6, wherein the thickness of the target epitaxy layer is within 35-50 μm.

8. A method of making a standard wafer for resistivity measurement, the standard wafer being utilized for calibration before measuring a resistivity of an Epi wafer having a first conductive type, comprising steps of:
providing a silicon substrate having a second conductive type which is opposite to the first conductive type;
forming a target epitaxy layer overlying the silicon substrate, the target epitaxy layer having the first conductive type, a resistivity of the target epitaxy layer being greater than 50 ohm/cm, and a thickness of the target epitaxy layer being greater than 35 μm; and
measuring a measurement of the resistivity of the target epitaxy layer with four point probing, the measurement being utilized as a standard resistivity of the standard wafer, and the first conductive type of the target epitaxy layer being utilized as a conductive type of the standard wafer.

9. A standard wafer for resistivity measurement, wherein the standard wafer is made with the method of making a standard wafer according to claim 1.

10. A calibration method, performing calibration before measuring a resistivity of an Epi wafer with a standard wafer or resistivity measurement according to claim 9, comprising steps of:
obtaining a conductive type and a predicted range of resistivity of an Epi wafer;
choosing at least two of the standard wafers, the conductive type of which is the same as the conductive type of the Epi wafer, and a range of a standard resistivity of the standard wafer overlapping the predicted range of resistivity; and
utilizing the standard wafer to perform a calibration before measuring the resistivity of the Epi wafer.
